(19) United States
(12) Patent Application Publication
(10) Pub. No.: US 2024/0395957 A1
(43) Pub. Date: Nov. 28, 2024

(54) PHOTOVOLTAIC MODULE, MANUFACTURING METHOD FOR PHOTOVOLTAIC MODULE, AND MACHINING DEVICE

(71) Applicants: JINKO SOLAR CO., LTD., SHANGRAO (CN); ZHEJIANG JINKO SOLAR CO., LTD., HAINING, ZHEJIANG (CN)

(72) Inventors: Wusong TAO, SHANGRAO (CN); Luchuang WANG, SHANGRAO (CN); Niannian QIN, SHANGRAO (CN)

(21) Appl. No.: 18/362,944

(22) Filed: Jul. 31, 2023

(30) Foreign Application Priority Data
May 26, 2023 (CN) 202310609235.X
May 26, 2023 (CN) 202310610355.1

(51) Int. Cl. H01L 31/05

(52) U.S. Cl. CPC H01L 31/0508

(57) ABSTRACT

The present disclosure relates to a photovoltaic module, a manufacturing method for a photovoltaic module, and a machining device. The photovoltaic module includes solar cell strings and electrode lines. Each of the solar cell strings includes solar cells arranged in parallel, and each of the electrode lines is located on a side of a corresponding solar cell and configured to connect adjacent solar cells to form the solar cell strings. soldering regions are arranged apart along a length direction of the photovoltaic module, connecting members are arranged in the soldering regions, each of the electrode lines is located on a side of a corresponding solar cell provided with the connecting members on the side.

### TECHNICAL FIELD

The present disclosure relates to the technical field of photovoltaic power generation, and in particular, to a photovoltaic module, a manufacturing method for a photovoltaic module, and a machining device.

### BACKGROUND

In the design of a rear-contact solar cell, positive and negative electrodes of the solar cell are both designed on a rear surface of the solar cell, and at the same time, gate lines and connection points on a far side of the solar cell almost fit edges of a silicon wafer of the solar cell. During soldering of solar cells into a solar cell string, there is a greater risk of problems such as cold soldering at the connection points, which reduces a yield of manufacturing of the solar cell.

### SUMMARY

The present disclosure provides a photovoltaic module, a manufacturing method for a photovoltaic module, and a machining device to solve the problem that cold soldering easily occurs at connection points of solar cells.

Some embodiments of the present disclosure provide a photovoltaic module, the photovoltaic module including:

a solar cell string including solar cells which are arranged in parallel along a length direction of the photovoltaic module; and

electrode lines, each of the electrode lines being located on a side of a corresponding solar cell and configured to connect adjacent solar cells,

wherein soldering regions are arranged on a side of each of the solar cells facing the electrode lines, and arranged apart along the length direction of the photovoltaic module, the electrode lines are connected to the soldering regions, connecting members are arranged between the soldering regions and the electrode lines, the electrode lines are connected to the soldering regions through the connecting members, and each of the connecting members includes a first region and a second region, the second region being arranged around the first region, and transparency of the second region being greater than transparency of the first region.

In an embodiment, the second region has a width less than or equal to 30 μm.

In an embodiment, the second region has a surface pore density less than that of

the first region.

In an embodiment, at least one recessed portion is arranged on a surface of the first region.

In an embodiment, in the first region, an arrangement density of the at least one recessed portion an arrangement density ranges from 100 pcs/mm² to 2000 pcs/mm².

In an embodiment, along a thickness direction of the photovoltaic module, a projection of the at least one recessed portion is located outside projections of the electrode line.

In an embodiment, the at least one recessed portion comprises a plurality of

recessed portions arranged on the surface of the first region, the recessed portions are arranged apart from each other on a surface of the first region.

In an embodiment, the at least one recessed portion comprises a plurality of recessed portions arranged on the surface of the first region, and adjacent recessed portions of the plurality of recessed portions (133) are interconnected with each other.

In an embodiment, along a thickness direction of the photovoltaic module, a projection of each of the at least one recessed portion in a corresponding solar cell is in a shape of a circle or an ellipse.

In an embodiment, along a thickness direction of the photovoltaic module, a projection of each of the at least one recessed portion in the solar cell has a size ranging from 3 μm to 15 μm along a width direction of the photovoltaic module.

In an embodiment, the first region is provided with a solder paste.

Some embodiments of the present disclosure further provide a method for manufacturing a photovoltaic module, the photovoltaic module including a solar cell string, a back sheet, an adhesive film, and photovoltaic glass, and the solar cell string including solar cells, electrode lines, and connecting members, wherein the method includes: placing the connecting members in soldering regions of the solar cells; placing the solar cells with the connecting members on an operating platform; placing each of the electrode lines on a side of a corresponding solar cell provided with the connecting members on thereon side; heating the electrode lines and the connecting members to obtain the solar cell string; and laminating the back sheet, the adhesive film, the solar cell strings, and the photovoltaic glass to obtain the photovoltaic module.

In an embodiment, each of the solar cells includes a positive busbar and a negative busbar, the positive busbars and the negative busbars are alternately arranged along a width direction of the photovoltaic module, and when the solar cells with the connecting members are placed on the operating platform, and the method for manufacturing a photovoltaic module includes: rotating one of two adjacent solar cells by 180° such that, in the adjacent solar cells, the positive busbar of one of the two adjacent solar cells and the negative busbar of the other of the two adjacent solar cells are located on a same straight line along a length direction of the photovoltaic module.

In an embodiment, the heating the electrode lines and the connecting members to obtain the solar cell string is performed at a heating temperature ranging from 130° C. to 220° C. for 1.5 s to 6 s.

In an embodiment, the heating the electrode lines and the connecting members to obtain the solar cell string is performed at a heating temperature ranging from 230° C. to 240° C., for no more than 5 s.

Some embodiments of the present disclosure further provide a machining device, for manufacturing a photovoltaic module, the photovoltaic module including solar cells, electrode lines, and connecting members, and the machining device includes: an operating platform, the solar cells being located on a surface of the operating platform; a pressing tool, the pressing tool being located on one side of the operating platform where the solar cells are placed; and a heating apparatus, the heating apparatus being configured to heat the solar cells and the connecting members.

In an embodiment, the heating apparatus is located in the operating platform, and the solar cells are placed in the heating apparatus.

In an embodiment, the heating apparatus is a curing furnace, and the operating platform is capable of entering the curing furnace;

the curing furnace including a heating member, and the heating member being located on a side of a corresponding solar cell away from the operating platform.

In an embodiment, the pressing tool includes a bracket and abutting members, and the bracket is arranged parallel to each of the electrode lines along a height direction of the machining device electrode line, and each of the abutting members has one end connected to the bracket and another end capable of abutting against one of the electrode lines.

In an embodiment, the pressing tool further includes elastic members, and the bracket and the abutting members are connected to each other through the elastic members.

It should be understood that the general description above and the detailed description in the following are merely exemplary and illustrative, and cannot limit the present disclosure.

### BRIEF DESCRIPTION OF DRAWINGS

FIG. 1 is a schematic structural diagram of solar cells according to some embodiments of the present disclosure;

FIG. 2 is a schematic structural diagram of solar cells and connecting members according to some embodiments of the present disclosure;

FIG. 3 is a schematic structural diagram of solar cell strings according to some embodiments of the present disclosure;

FIG. 4 is a schematic structural diagram of a machining device according to some embodiments of the present disclosure;

FIG. 5 is a microstructural diagram of a connecting member according to some embodiments of the present disclosure;

FIG. 6 is a partial enlarged view of the connecting member according to some embodiments of the present disclosure;

FIG. 7 is a schematic structural diagram of the connecting member according to some embodiments of the present disclosure;

FIG. 8 is a microstructural diagram of a connecting member according to some other embodiments of the present disclosure;

FIG. 9 is a partial enlarged view of the connecting member according to some other embodiments of the present disclosure;

FIG. 10 is a schematic structural diagram of a connecting member according to some other embodiments of the present disclosure; and

FIG. 11 is a schematic structural diagram of a connecting member according to some other embodiments of the present disclosure.

### REFERENCE SIGNS

1: solar cell string;
   11: solar cell;
      111: soldering region;
   12: electrode line;
   13: connecting member;
      131: first region;
      132: second region;
      133: recessed portion;
      134: third region;
   2: operating platform;
   3: pressing tool;
      31: bracket;
      32: abutting member;
      33: elastic member.

The accompanying drawings herein are incorporated in and constitute a part of this specification, illustrate embodiments consistent with the present disclosure and, together with the specification, serve to explain the principles of the present disclosure.

### DESCRIPTION OF EMBODIMENTS

In order to better understand the technical solution of the present disclosure, embodiments of the present disclosure are described in detail below with reference to the accompanying drawings.

It is to be made clear that the described embodiments are only some rather than all of the embodiments of the present disclosure. All other embodiments obtained by those of ordinary skill in the art based on the embodiments in the present disclosure without creative efforts fall within the protection scope of the present disclosure.

The terms used in the embodiments of the present disclosure are intended only to describe particular embodiments and are not intended to limit the present disclosure. As used in the embodiments of the present disclosure and the appended claims, the singular forms of “a/an”, “the”, and “said” are intended to include plural forms, unless otherwise clearly specified by the context.

It is to be understood that the term “and/or” used herein is merely an association relationship describing associated objects, indicating that three relationships may exist. For example, A and/or B indicates that there are three cases of A alone, A and B together, and B alone. In addition, the character “/” herein generally means an “or” relationship between the associated objects.

It is to be noted that the location terms such as “above”, “below”, “left”, and “right” described in the embodiments of the present disclosure are described with reference to the angles shown in the accompanying drawings, and should not be construed as limitations on the embodiments of the present disclosure. In addition, in the context, it is to be further understood that, when one element is referred to as being connected “above” or “below” another element, the one element may be directly connected “above” or “below” another element, or connected “above” or “below” another element via an intermediate element.

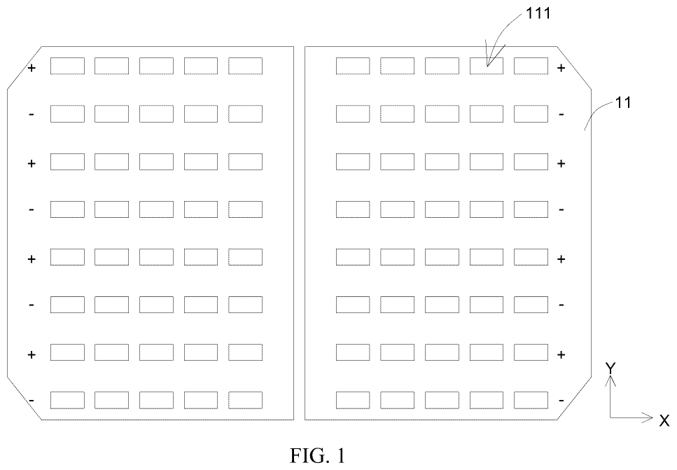

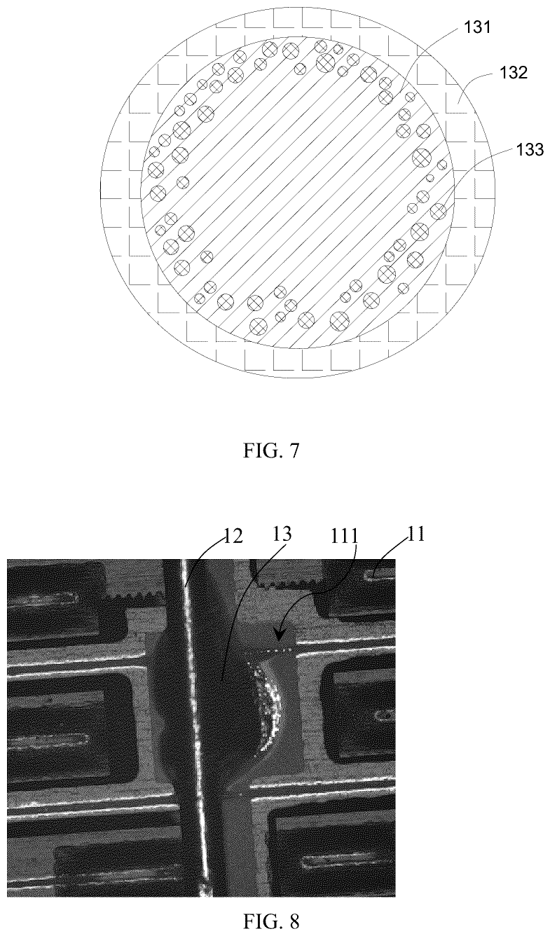

As shown in FIG. 1 to FIG. 7, some embodiments of the present disclosure provide a photovoltaic module, including solar cell strings 1 and electrode lines 12. The solar cell strings 1 each include solar cells 11 arranged in parallel. The electrode lines 12 are located on one sides of the solar cells 11 and configured to connect adjacent solar cells 11. soldering regions 111 are arranged on one sides of the solar cells 11 facing the electrode lines 12. The soldering regions 111 are arranged apart along a length direction X of the photovoltaic module. Connecting members 13 are arranged in the soldering regions 111, such that the electrode lines 12 are connected to the soldering regions 111 of the solar cells 11 through the connecting members 13. The connecting members 13 each include a first region 131 and a second region 132. The second region 132 is arranged around the first region 131, and transparency of the second region 132 is greater than that of the first region 131.

The solar cell 11 provided in some embodiments of the present disclosure is a rear-back solar cell 11. A positive busbar and a negative busbar in the solar cell 11 are both located on a same side of the solar cell 11. The soldering region 111 is arranged on the positive busbar and the negative busbar of the solar cell 11. The electrode line 12 is configured to connect the positive busbars and the negative busbars between adjacent solar cells 11. Therefore, along a thickness direction Z of the photovoltaic module, the electrode lines 12 can be located on a same side of the adjacent solar cells 11.

The positive busbar and the negative busbar of the rear-back solar cell 11 are both designed on a rear surface of the solar cell, and at the same time, a solder joint between a busbar and the electrode line 12 at an edge almost fit an edge of the solar cell 11. Therefore, there is a greater risk of problems such as cold soldering during the soldering. The arrangement of the connecting member 13 in the soldering region 111 can reduce a possibility of cold soldering between the electrode line 12 and the solar cell 11, helping to increase a yield of the photovoltaic module. Main components of the connecting member 13 are different metals such as tin-lead or tin-bismuth-silver, and organic solvents such as flux are also added to the connecting member 13 to facilitate soldering of the electrode line 12 and the solar cell 11. During the soldering, the connecting member 13 is heated and melted, and the organic solvents in the connecting member 13 may precipitate along a direction from the first region 131 to the second region 132. After the soldering, the precipitated organic solvents may gather at edges of the first region 131 in the connecting member 13 to form the second region 132. Due to greater transparency of the organic solvents, the transparency of the second region 132 is approximately 70% to 80% greater than the transparency of the first region 131.

In some possible embodiments, after the electrode line 12 is connected to the soldering region 111, the connecting member 13 has a recessed portion 133 on a surface.

Main components of the connecting member 13 are different metals such as tin-lead or tin-bismuth-silver, and organic solvents are also added to the connecting member 13 to facilitate soldering of the electrode line 12 and the solar cell 11. When the connecting member 13 is heated, the organic solvents may volatilize by heat, and a recessed portion 133 may be formed on the surface of the connecting member 13. After the organic solvents volatilize, it is beneficial to improve strength of the soldering between the electrode line 12 and the solar cell 11.

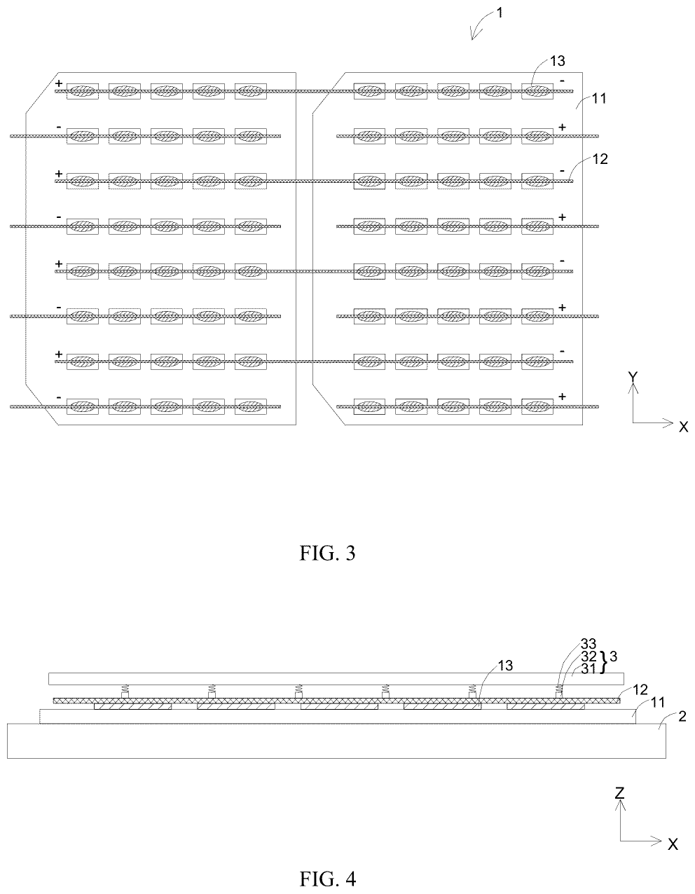

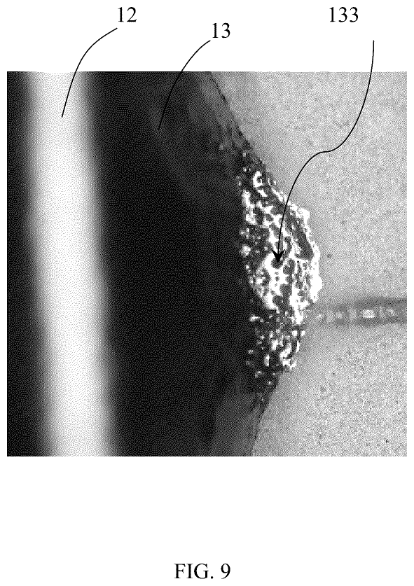

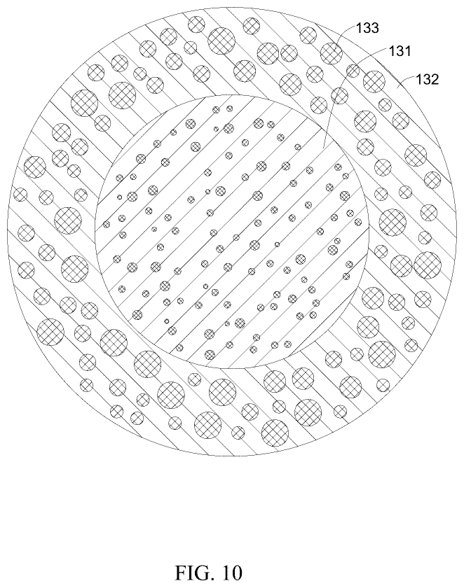

As shown in FIG. 3, FIG. 9, and FIG. 10, in some possible embodiments, along the thickness direction Z of the photovoltaic module, the electrode line 12 overlaps with the connecting member 13, and in projections along the thickness direction Z of the photovoltaic module, the projection of the recessed portion 133 on the solar cell 11 is located outside a projection region of the electrode line 12 on the solar cell 11.

In some possible embodiments, in the projections along the thickness direction Z of the photovoltaic module, the projection of the recessed portion 133 on the solar cell 11 overlaps with the projection of the electrode line 12 on the solar cell 11, such that the recessed portion 133 also exists at a position where the electrode line 12 overlaps with the connecting member 13.

When the connecting member 13 is heated, the organic solvents in the connecting member 13 volatilize when the connecting member 13 is not completely cured, such that the connecting member 13 has the recessed portion 133 on the surface after curing. Before the connecting member 13 is heated, the organic solvents are evenly mixed with other components in the connecting member 13. Therefore, the recessed portion 133 formed due to the volatilization of the organic solvents may overlap with the electrode line 12 or may not overlap with the electrode line 12. When the recessed portion 133 overlaps with the electrode line 12, an area of contact between the electrode line 12 and the connecting member 13 may be reduced, so strength of the connection between the electrode line 12 and the connecting member 13 may be reduced. Therefore, in an ideal state, the projection of the recessed portion 133 is located outside the projection of the electrode line 12.

As shown in FIG. 9 and FIG. 10, in some possible embodiments, the connecting member 13 has recessed portions 133 on the surface, and the recessed portions 133 are arranged apart.

During the volatilization of the organic solvents, gaseous organic solvents may form bubbles on the surface of the connecting member 13. As the gaseous organic solvents in the bubbles gradually increase, the bubbles break to form recessed portions 133 on the surface of the connecting member 13. During the gasification of the organic solvents, adjacent organic solvents may gather into a bubble and then volatilize from the connecting member 13, such that the recessed portions 133 on the surface of the connecting member 13 are arranged apart.

In some possible embodiments, the connecting member 13 has recessed portions 133 on the surface, and adjacent recessed portions 133 are interconnected with each other.

In the case of more organic solvents in the connecting member 13 or a higher heating temperature, reaction is violent when the organic solvents volatilize, such that bubbles may be formed multiple times at a same position or similar positions on the surface of the connecting member 13. After breakage of the bubbles, recessed portions 133 interconnected with each other may be formed.

As shown in FIG. 10, in some possible embodiments, the connecting member 13 includes a first region 131 and a second region 132, wherein the second region 132 is arranged around the first region 131. Both the first region 131 and the second region 132 are provided with the recessed portions 133, and an average size of the recessed portions 133 in the first region 131 is smaller than an average size of the recessed portions 133 in the second region 132.

When the connecting member 13 is heated, the organic solvents in the connecting member 13 have one part that may volatilize in the first region 131 and the other part that may flow from the first region 131 to the second region 132 and then volatilize in the second region 132, such that the organic solvents volatilizing in the first region 131 are smaller than the organic solvents volatilizing in the second region 132. Therefore, sizes of the recessed portions 133 in the first region 131 are smaller than sizes of the recessed portions 133 in the second region 132, and it is also possible that a number of the recessed portions 133 in the first region 131 is less than that of the recessed portions 133 in the second region 132.

In some possible embodiments, arrangement density of the recessed portions 133 in the second region 132 ranges from 3×10³ pcs/mm² to 13×10⁴ pcs/mm².

| The arrangement density of the recessed portions 133 in the second region 132 may be 3×10³ pcs/mm², 13×10³ pcs/mm², 23×10³ pcs/mm², 33×10³ pcs/mm², 43×10³ pcs/mm2, 53×10³ pcs/mm², 63×10³ pcs/mm², 73×10³ pcs/mm², 83×10³ pcs/mm², 93×10³ pcs/mm2, 3×10⁴ pcs/mm², 13×10⁴ pcs/mm², or the like. If the number of the recessed portions 133 in the second region 132 is less than 3×10³ pcs/mm², an effect of volatilization of the organic solvents may be reduced, resulting in residues of the organic solvents in the second region 132, thereby reducing reliability of the soldering between the electrode line 12 and the solar cell 11. If the number of the recessed portions 133 in the second region 132 is greater than 3×10⁴ pcs/mm², an area of contact between the connecting member 13 in the second region 132 and the electrode line 12 may be reduced, and strength of the connection between the second region 132 and the electrode line 12 may be reduced.

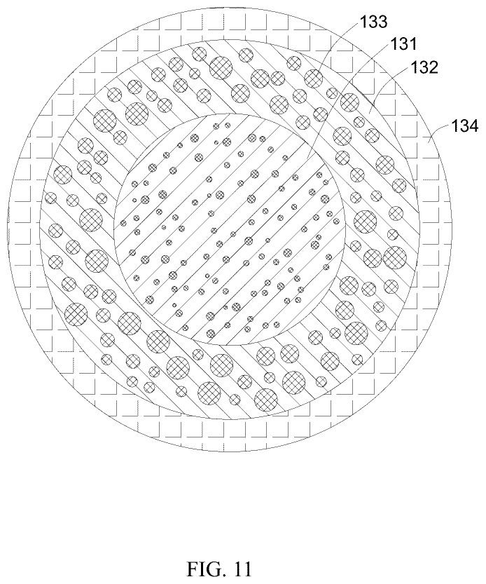

As shown in FIG. 11, in some possible embodiments, the connecting member 13 further includes a third region 134, and the third region 134 is arranged around the second region 132. During the heating of the connecting member 13, the organic solvents may precipitate along a direction from the first region 131 to the second region 132. During the precipitation, part of the organic solvents may volatilize in the first region 131 and the second region 132, such that recessed portions 133 are formed in the first region 131 and the second region 132, and some non-volatilizing organic solvents may continue to precipitate to edges of the second region 132, forming a third region 134 around the second region 132.

Along a width direction Y of the photovoltaic module, a width of the third region 134 is less than that of the second region 132. During the heating of the connecting member 13, most of the organic solvents may volatilize in the first region 131 or the second region 132, and a small part of the organic solvents may form the third region 134. Therefore, the width of the third region 134 is less than that of the second region 132.

The third region 134 is composed of non-volatilizing organic solvents. Therefore, the third region 134 includes no recessed portions 133 formed due to the volatilization of the organic solvents. arrangement density of the recessed portions 133 in the first region 131 may range from 100 pcs/mm² to 2000 pcs/mm². For example, the arrangement density of the recessed portions 133 in the first region 131 may be 100 pcs/mm², 500 pcs/mm², 1000 pcs/mm², 1500 pcs/mm², 2000 pcs/mm², or the like. Compared with the first region 131 and the second region 132, arrangement density of the recessed portions 133 in the third region 134 may range from 0 to 100 pcs/mm². For example, the arrangement density of the recessed portions 133 in the third region 134 may be 0, 20 pcs/mm², 40 pcs/mm², 60 pcs/mm², 80 pcs/mm², 100 pcs/mm^{2,} or the like. Therefore, the third region 134 has higher flatness than the first region 131 and the second region 132. In the first region 131 and the second region 132 of the connecting member 13, the organic solvents precipitate, main components are tin-lead, tin-bismuth-silver, or the like, and transparency thereof is less than that of the organic solvents. Transparency of the third region 134 is approximately 70% to 80%, which may be, for example, 70%, 75%, 80%, or the like. The first region 131 and the second region 132 are opaque or less transparent than the third region 134.

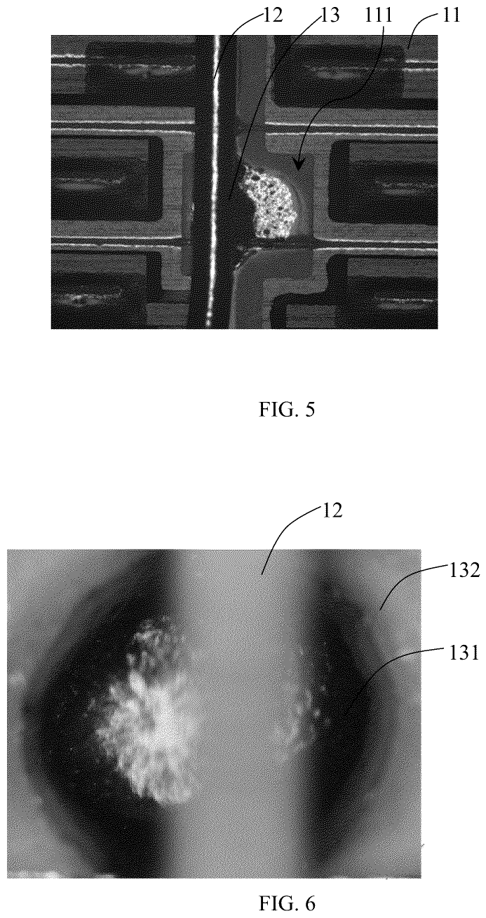

As shown in FIG. 5 to FIG. 7, in some possible embodiments, the first region 131 has recessed portions 133 on the surface. In the projections along the thickness direction of the photovoltaic module, the projection of the recessed portion 133 on the solar cell 11 is located outside a range of the projection of the electrode line 12 on the solar cell 11.

The electrode line 12 is connected to the solar cell 11 through the connecting member 13. Therefore, the electrode line 12 has an overlapping portion with the first region 131. If the recessed portion 133 is arranged in the overlapping portion between the electrode line 12 and the first region 131, the area of contact between the electrode line 12 and the connecting member 13 may be reduced, resulting in a decrease in the strength of the connection between the electrode line 12 and the connecting member 13. If the recessed portion 133 in the first region 131 is outside an overlapping region between the electrode line 12 and the first region 131, an influence of the recessed portion 133 on the strength of the connection between the electrode line 12 and the connecting member 13 can be reduced.

In some possible embodiments, along the width direction Y of the photovoltaic module, the width of the second region 132 is less than or equal to 30 μm.

In the connecting member 13, one part of the organic solvents volatilize during the soldering, and the other part of the organic solvents precipitate to form the second region 132.

If the width of the second region 132 is greater than 30 μm, content of the organic solvents in the connecting member 13 is more, resulting in precipitation of more organic solvents, and there may be residues of the organic solvents in the first region 131, affecting strength of the soldering between the electrode line 12 and the solar cell 11.

In some possible embodiments, the recessed portion 133 is formed by the breakage of the bubbles formed by the gasification of the organic solvents in the connecting member 13. Therefore, in the projections along the thickness direction Z of the photovoltaic module, the projection of the recessed portion 133 in the solar cell 11 is in a shape of a circle or an ellipse.

Since the projection of the recessed portion 133 along the thickness direction Z of the photovoltaic module is in the shape of a circle or an ellipse, the recessed portion 133 may be hemispherical or cylindrical, which facilitates the organic solvents to volatilize from the connecting member 13, reducing the residues of the organic solvents in the connecting member 13, and helping to improve the reliability of the soldering between the electrode line 12 and the solar cell 11.

In some possible embodiments, along the width direction of the photovoltaic module, the size of the recessed portion 133 ranges from 3 μm to 15 μm.

The size of the recessed portion 133 may be 3 μm, 6 μm, 9 μm, 12 μm, 15 μm, or the like, which is 9 μm in some embodiments. If a width of the recessed portion 133 is less than 3 μm, an effect of volatilization of the organic solvents in the connecting member 13 may be reduced. If the width of the recessed portion 133 increases, it is easier for the organic solvents to volatilize. Along the width direction Y of the photovoltaic module, a width of the connecting member 13 ranges from 0.2 mm to 1 mm. If the width of the recessed portion 133 is greater than 15 μm, the recessed portion 133 accounts for a larger portion in the connecting member 13, which may affect the strength of the connection between the electrode line 12 and the connecting member 13.

As shown in FIG. 5 to FIG. 7, in some possible embodiments, the organic solvents in the connecting member 13 have one part volatilizing in the first region 131 to form the recessed portions 133 and the other part precipitating from the first region 131 to form the second region 132. The arrangement density of the recessed portions 133 in the first region 131 may range from 100 pcs/mm2 to 2000 pcs/mm². For example, the arrangement density of the recessed portions 133 in the first region 131 may be 100 pcs/mm², 500 pcs/mm², 1000 pcs/mm², 1500 pcs/mm², 2000 pcs/mm², or the like. The arrangement density of the recessed portions 133 in the second region 132 may be 0, 20 pcs/mm², 40 pcs/mm², 60 pcs/mm², 80 pcs/mm², 100 pcs/mm², or the like. The arrangement density of the recessed portions 133 in the second region 132 is lower. Therefore, the second region 134 has lower pore density and higher flatness.

In some possible embodiments, the first region 131 may be solder paste. The solder paste may improve capillarity and wettability, and reduce a possibility of cold soldering between the electrode line 12 and the solar cell 11. At the same time, the solder paste may also isolate the air to prevent oxidation of solder joints between the electrode line 12 and the solar cell 11, helping to improve the reliability of the soldering between the electrode line 12 and the solar cell 11.

The solar cells 11 arranged in parallel are connected into the solar cell string 1 through the electrode line 12, an upper surface and a lower surface of the solar cell string 1 are both provided with adhesive films, the upper surface of the solar cell string 1 is further provided with photovoltaic glass connected to the solar cell string 1 through the adhesive film, and the lower surface of the solar cell string 1 is further provided with photovoltaic glass or a back sheet which is also connected to the solar cell string 1 through the adhesive film to form the photovoltaic module.

Some embodiments of the present disclosure further provide a manufacturing method for manufacturing a photovoltaic module for a photovoltaic module. The photovoltaic module includes solar cell strings 1, a back sheet, an adhesive film, and photovoltaic glass. The solar cell string 1 includes solar cells 11, a electrode line 12, and connecting members 13. The electrode line 12 is connected to the solar cells 11 through the connecting members 13.

The method for manufacturing a photovoltaic module includes:
S1: placing the connecting members 13 in soldering regions 111 of the solar cells 11;
S2: placing the solar cells 11 with the connecting members 13 on an operating platform 2;
S3: placing the electrode line 12 on one sides of the solar cells 11 provided with the connecting members 13;
S4: heating the electrode line 12 and the connecting members 13 to obtain the solar cell string 1; and
S5: laminating the back sheet, the adhesive film, the solar cell strings 1, and the photovoltaic glass to obtain the photovoltaic module.

The connecting member 13 is arranged between the electrode line 12 and the solar cell 11, which can improve the strength of the connection between the electrode line 12 and the solar cell 11 and reduce a possibility of cold soldering. Both the connecting member 13 and the electrode line 12 are placed on a surface of the solar cell 11, which omits the step of curing the connecting member 13 on the solar cell 11, helping to improve manufacturing efficiency of the solar cell string 1.

When the connecting members 13 are placed in the soldering regions 111 of the solar cells 11, the method for manufacturing a photovoltaic module includes: S11: printing the connecting members 13 in the soldering regions 111 of the solar cells 11.

The connecting member 13 is arranged in the soldering region 111 by printing, which facilitates the control over a position and a shape of the connecting member 13, enabling the connecting member 13 to be located at a position where the electrode line 12 and the solar cell 11 are soldered. When the electrode line 12 is soldered to the solar cell 11, the connecting member 13 can reduce a possibility of colder soldering.

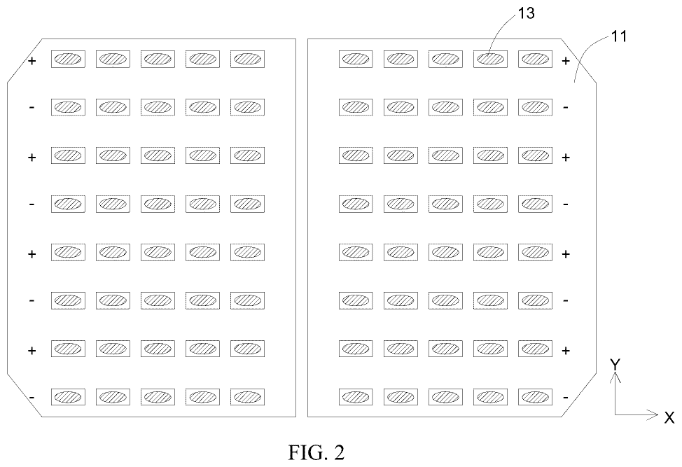

As shown in FIG. 2 and FIG. 3, in some possible embodiments, the solar cell 11 includes a positive busbar and a negative busbar, the positive busbars and the negative busbars are alternately arranged on the solar cells 11 along a width direction Y of the photovoltaic module, and positions of the positive busbars and the negative busbars in the solar cells 11 are consistent. Therefore, when the solar cells 11 are placed on the operating platform 2, along a length direction X of the photovoltaic module, in adjacent solar cells 11, the positive busbars are located on a same straight line and the negative busbars are located on a same straight line.

When the solar cells 11 with the connecting members 13 are placed on the operating platform 2, the method for manufacturing a photovoltaic module includes: S21: rotating one of two adjacent solar cells 11 by 180° such that, in the adjacent solar cells 11, the positive busbar of one and the negative busbar of the other are located on a same straight line along the length direction X of the photovoltaic module.

The electrode line 12 is configured to connect the positive busbars and the negative busbars in the adjacent solar cells 11, and in the adjacent solar cells 11, the positive busbar of one and the negative busbar of the other are located on a same straight line, such that the electrode line 12 can be arranged on one side of the solar cell 11 provided with the positive busbar and the negative busbar.

After the electrode lines 12 are placed on one sides of the solar cells 11 provided with the connecting members 13, the method for manufacturing a photovoltaic module includes: S31: fixing the electrode lines 12 to the sides of the solar cells 11 provided with the connecting members 13.

A force is applied to the electrode line 12 on a side of the electrode line 12 away from the solar cell 11 to fix the electrode line 12 to the solar cell 11, which reduces a possibility of displacement of the electrode line 12 during subsequent soldering between the electrode line 12 and the solar cell 11, helping to increase a yield of the solar cell string 1.

In some possible embodiments, the operating platform 2 for placing the solar cell 11 can heat the solar cell 11 and then solder the solar cell 11 and the electrode line 12.

When the solar cells 11 are heated to obtain the solar cell string 1, the method for manufacturing a photovoltaic module includes: a heating temperature ranging from 130° C. to 220° C., and heating time ranging from 1.5 s to 6 s.

During the heating, the solar cell 11 transfers heat emitted by a heating platform to the connecting member 13 and the electrode line 12, causing the connecting member 13 to melt to connect the electrode line 12 and the solar cell 11. During the heating, the heating temperature may be 130° C., 150° C., 170° C., 190° C., 210° C., 220° C., or the like, and the heating time may be 1.5 s, 2.5 s, 3.5 s, 4.5 s, 5.5 s, 6 s, or the like. The organic solvents in the connecting member 13 have one part volatilizing in the first region 131 to form recessed portions 133 and the other part precipitating from the first region 131 to form the second region 132.

In some possible embodiments, a heating apparatus is arranged on one side of the solar cell 11 away from the operating platform 2. The heating apparatus may be an infrared lamp box. The electrode line 12 and the connecting member 13 are heated by the heating apparatus, thereby soldering the solar cell 11 and the electrode line 12.

When the solar cells 11 are heated to obtain the solar cell string 1, the method for manufacturing a photovoltaic module includes: a heating temperature ranging from 230° C. to 240° C., and heating time being less than or equal to 5 s.

When the solar cell 11 is heated, the heating temperature may be 230° C., 235° C., 240° C., or the like. In the manner of heating the connecting member 13 and the electrode line 12 through the infrared heating apparatus, the solar cell 11 is not required to transfer heat, and at the same time, the infrared heating apparatus can provide a higher temperature. Therefore, the soldering between the electrode line 12 and the solar cell 11 can be completed when the heating time is less than or equal to 5 s.

In some possible embodiments, when the connecting members 13 are placed in the soldering regions 111 of the solar cells 11, the method for manufacturing a photovoltaic module includes: fixing the connecting members 13 to the solar cells 11 by heating.

The connecting member 13 is first fixed to the solar cell 11 by heating, which limits a relative position between the connecting member 13 and the solar cell 11. In the step of soldering the electrode line 12 and the solar cell 11 through the connecting member 13, a possibility of displacement of the connecting member 13 is reduced, and a possibility of colder soldering between the electrode line 12 and the solar cell 11 is reduced.

The connecting member 13 may be solder paste. When the connecting members 13 are fixed to the solar cells 11 by heating, the method for manufacturing a photovoltaic module includes: S21: heating the solder paste to 120° C. to 180° C. for 10 s to 60 s.

The solar cell 11 printed with the solder paste is placed in a curing furnace for heating. A heating temperature may be 120° C., 130° C., 140° C., 150° C., 160° C., 170° C., 180° C., or the like, and heating time may be 10 s, 20 s, 30 s, 40 s, 50 s, 60 s, or the like. The solder paste is cured and fixed to the solar cell 11. The solder paste includes organic solvents such as flux. During the curing of the solder paste, the organic solvents such as flux in the solder paste may volatilize or precipitate from a center of the solder paste to edges, which reduces content of the organic solvents in the solder paste and can improve strength of the soldering between the electrode line 12 and the solar cell 11.

Some embodiments of the present disclosure further provide a machining device, for manufacturing a photovoltaic module. The machining device includes an operating platform 2, pressing tools 3, and a heating apparatus. The pressing tool 3 is mounted on the operating platform 2 and configured to limit positions of solar cells 11 and electrode lines 12 in the photovoltaic module. The heating apparatus is configured to heat connecting members 13 and the electrode lines 12.

The solar cell 11 is placed on the operating platform 2. One side of the solar cell 11 provided with no positive busbar and no negative busbar faces the operating platform 2. The pressing tool 3 includes a bracket 31 and abutting members 32. The bracket 31 is configured to fix positions of the abutting members 32, such that the abutting members 32 are located above the electrode line 12. The abutting members 32 are connected to the bracket 31 through an elastic member 33. When the pressing tool 3 fixes the position of the electrode line 12, one ends of the abutting members 32 away from the bracket 31 abut against the electrode line 12 and may compress the elastic member 33 at the same time. An elastic force of the elastic member 33 may be transferred to the electrode line 12 through the abutting members 32, such that the electrode line 12 is fixed to the solar cells 11, facilitating heating of the solar cells 11, the connecting members 13, and the electrode line 12 to form the solar cell string 1.

In some possible embodiments, the heating apparatus is located in the operating platform 2, the solar cell 11 can be placed on a surface of the heating apparatus, and the solar cell 11 is heated through the heating apparatus to melt the connecting member 13 and then connect the electrode line 12 and the solar cell 11.

Through the arrangement of the heating apparatus in the operating platform 2, one side of the solar cell 11 provided with the busbars can be heated, heat is transferred, through the solar cell 11, to the side of the solar cell 11 provided with the busbars to heat the connecting member 13 and the electrode line 12, and then the electrode line 12 and the solar cell 11 can be connected.

In some possible embodiments, the heating apparatus is a curing furnace, a heating member is arranged in the curing furnace, the solar cell 11 can enter the curing furnace along with the operating platform 2, the heating member is located on one side of the solar cell 11 where the connecting member 13 and the electrode line 12 are placed, and the solar cell 11, the connecting member 13, and the electrode line 12 are heated through the heating member, to connect the electrode line 12 and the solar cell 11.

The heating member may be an infrared heating apparatus, and the connecting member 13 and the electrode line 12 can be directly heated through the infrared heating apparatus. At the same time, a heating temperature of the infrared heating apparatus is higher, such that the connecting member 13 can melt more easily and then connect the electrode line 12 and the solar cell 11.

As shown in FIG. 4, in some possible embodiments, the pressing tool 3 includes a bracket 31 and abutting members 32. The bracket 31 is configured to fix positions of the abutting members 32. The abutting members 32 are configured to provide forces for the electrode line 12. The abutting members 32 are connected to the bracket 31 through an elastic member 33. When the pressing tool 3 fixes the position of the electrode line 12, one ends of the abutting members 32 away from the bracket 31 abut against the electrode lines 12 and may compress the elastic member 33 at the same time. An elastic force of the elastic member 33 may be transferred to the electrode line 12 through the abutting members 32, such that the electrode line 12 is fixed to the solar cells 11.

Through the operating platform 2 and the pressing tool 3, relative positions of the solar cell 11 and the electrode line 12 can be limited, which reduces a possibility of displacement of the electrode line 12 during the soldering and helps to increase a yield of the photovoltaic module.

In some possible embodiments, the machining device further includes a heating apparatus and a soldering apparatus. The heating apparatus and the soldering apparatus are located upstream of the operating platform and downstream of the operating platform respectively. After the connecting members are arranged on the surface of the solar cells, the heating apparatus is entered first, the connecting members are cured, and the connecting members are fixed to the solar cells. Then, the solar cells are placed on the operating platform, and relative positions of the electrode lines and the solar cells are limited through the pressing tools, which are finally placed in the soldering apparatus to solder the electrode lines and the solar cells.

Some embodiments of the present disclosure provide a photovoltaic module, a manufacturing method for manufacturing a photovoltaic module for a photovoltaic module, and a machining device. The photovoltaic module includes solar cell strings 1 and electrode lines 12. The solar cell string 1 includes solar cells 11 arranged in parallel, and the electrode line 12 is located on one sides of the solar cells 11 and configured to connect adjacent solar cells 11 to form the solar cell string 1. soldering regions 111 are arranged apart on the solar cell 11 along a length direction X of the photovoltaic module, connecting members 13 are arranged in the soldering regions 111, the electrode line 12 is located on one sides of the solar cells 11 provided with the connecting members 13, and the connecting members 13 can reduce a possibility of cold soldering between the electrode line 12 and the solar cells 11, helping to increase a yield of the solar cell string 1. The connecting member 13 includes a first region 131 and a second region 132. The second region 132 is arranged around the first region 131, and transparency of the second region 132 is greater than that of the first region 131.

The above are merely some embodiments of the present disclosure, and are not intended to limit the present disclosure. For those skilled in the art, the present disclosure may be subject to various modifications and changes. Any modification, equivalent replacement, improvement and the like within the spirit and principle of the present disclosure all fall within the protection scope of the present disclosure.

What is claimed is:

1. A photovoltaic module, comprising:
a solar cell string (1) comprising solar cells (11) which are arranged in parallel along a length direction of the photovoltaic module; and
electrode lines (12), each of the electrode lines (12) being located on a side of a corresponding solar cell (11) and configured to connect adjacent solar cells (11),
wherein soldering regions (111) are arranged on a side of each of the solar cells (11) facing the electrode lines (12), and arranged apart along the length direction of the photovoltaic module, the electrode lines (12) are connected to the soldering regions (111), connecting members (13) are arranged between the soldering regions (111) and the electrode lines (12), the electrode lines (12) are connected to the soldering regions (111) through the connecting members (13), and each of the connecting members (13) comprises a first region (131) and a second region (132),
wherein the second region (132) is arranged around the first region (131), and transparency of the second region (132) is greater than transparency of the first region (131).

2. The photovoltaic module according to claim 1, wherein the second region (132) has a width less than or equal to 30 μm.

3. The photovoltaic module according to claim 1, wherein the second region (132) has a surface pore density less than a surface pore density of the first region (131).

4. The photovoltaic module according to claim 1, wherein at least one recessed portion (133) is arranged on a surface of the first region (131).

5. The photovoltaic module according to claim 4, wherein, in the first region (131), an arrangement density of the at least one recessed portion (133) ranges from 100 pcs/mm² to 2000 pcs/mm².

6. The photovoltaic module according to claim 4, wherein, along a thickness direction of the photovoltaic module, a projection of the at least one recessed portion (133) is located outside projections of the electrode lines (12).

7. The photovoltaic module according to claim 4, wherein the at least one recessed portion comprises a plurality of recessed portions (133) arranged on the surface of the first region (131), and the plurality of recessed portions (133) are arranged apart from each other on the surface of the first region (131).

8. The photovoltaic module according to claim 4, wherein the at least one recessed portion comprises a plurality of recessed portions (133) arranged on the surface of the first region (131), and adjacent recessed portions (133) of the plurality of recessed portions (133) are interconnected with each other.

9. The photovoltaic module according to claim 4, wherein, along a thickness direction of the photovoltaic module, a projection of each of the at least one recessed portion (133) in a corresponding solar cell (11) is in a shape of a circle or an ellipse.

10. The photovoltaic module according to claim 4, wherein, along a thickness direction of the photovoltaic module, a projection of each of the at least one recessed portion (133) in the solar cell (11) has a size ranging from 3 μm to 15 μm along a width direction of the photovoltaic module.

11. The photovoltaic module according to claim 1, wherein the first region (131) is provided with a solder paste.

12. A method for manufacturing a photovoltaic module, wherein
the photovoltaic module comprises a solar cell string (1), a back sheet, an adhesive film, and photovoltaic glass, and the solar cell string (1) comprises solar cells (11), electrode lines (12), and connecting members (13), wherein the method comprises:
placing the connecting members (13) in soldering regions (111) of the solar cells (11);
placing the solar cells (11) with the connecting members (13) on an operating platform (2);
placing each of the electrode lines (12) on a side of a corresponding solar cell (11) provided with the connecting members (13) thereon;
heating the electrode lines (12) and the connecting members (13) to obtain the solar cell string (1); and
laminating the back sheet, the adhesive film, the solar cell strings (1), and the photovoltaic glass to obtain the photovoltaic module.

13. The method according to claim 12, wherein each of the solar cells (11) comprises a positive busbar and a negative busbar, the positive busbars and the negative busbars are alternately arranged along a width direction of the photovoltaic module, and when the solar cells (11) with the connecting members (13) are placed on the operating platform (2), the method comprises:
rotating one of two adjacent solar cells (11) by 180° such that, in the adjacent solar cells (11), the positive busbar of one of the two adjacent solar cells and the negative busbar of the other of the two adjacent solar cells are located on a same straight line along a length direction of the photovoltaic module.

14. The method according to claim 12, wherein the heating the electrode lines (12) and the connecting members (13) to obtain the solar cell string (1) is performed at a heating temperature ranging from 130° C. to 220° C. for 1.5 s to 6 s.

15. The method according to claim 12, wherein, the heating the electrode lines (12) and the connecting members (13) to obtain the solar cell string (1) is performed at a heating temperature ranging from 230° C. to 240° C. for no more than 5 s.

16. A machining device, for manufacturing a photovoltaic module comprising solar cells (11), electrode lines (12), and connecting members (13), wherein the machining device comprises:
an operating platform (2), wherein the solar cells (11) are located on a surface of the operating platform (2);
a pressing tool (3), located on a side of the operating platform (2) where the solar cells (11) are placed; and
a heating apparatus, configured to heat the solar cells (11) and the connecting members (13).

17. The machining device according to claim 16, wherein the heating apparatus is located in the operating platform (2), and the solar cells (11) are placed in the heating apparatus.

18. The machining device according to claim 16, wherein the heating apparatus is a curing furnace, and the operating platform (2) is capable of entering the curing furnace;
the curing furnace comprises a heating member, and the heating member is located on a side of a corresponding solar cell (11) away from the operating platform (2).

19. The machining device according to claim 16, wherein the pressing tool (3) comprises a bracket (31) and abutting members (32), and the bracket (31) is arranged parallel to each of the electrode lines (12) along a height direction of the machining device, and each of the abutting members (32) has one end connected to the bracket (31) and another end capable of abutting against one of the electrode lines (12).

20. The machining device according to claim 19, wherein the pressing tool (3) further comprises elastic members (33), and the bracket (31) and the abutting members (32) are connected to each other through the elastic members (33).
